(19) United States
(12) Patent Application Publication
(10) Pub. No.: US 2026/0333926 A1
(43) Pub. Date: Oct. 22, 2026

(54) INTEGRATED CIRCUIT DEVICE AND METHOD OF MANUFACTURING THE SAME

(71) Applicant: Taiwan Semiconductor Manufacturing Company, Ltd., Hsinchu (TW)

(72) Inventors: Yin-Kai Liao, Taipei City (TW); Hsing-Chih Lin, Tainan City (TW); Yi-Shin Chu, Hsinchu City (TW); Sung-Wen Huang Chen, Nantou County (TW)

(21) Appl. No.: 19/185,386

(22) Filed: Apr. 22, 2025

(51) Int. Cl. H10F 39/00; H10F 39/18; H10F 71/00

(52) U.S. Cl. CPC H10F 39/811; H10F 39/014; H10F 71/136; H10F 71/137; H10F 39/18; H10F 39/8053; H10F 39/8063

(57) ABSTRACT

In some embodiments, the present disclosure relates to an integrated circuit (IC) device including a support die having support circuitry and a photonic die having (a) an image-sensor portion having image-sensing circuitry and (b) a silicon-photonics portion having photonics features. The image-sensor portion and the silicon-photonics portion of the photonic die share an oxide layer having a plurality of bond pads at a first boundary of the oxide layer. The support die has an oxide layer including a plurality of bond pads at a first boundary of the oxide layer. The support die is bonded to the photonic die via the plurality of bond pads of the photonic die and the plurality of bond pads of the support die. The support circuitry is configured to provide support functionality to the image-sensor portion.

### BACKGROUND

Silicon-photonics (SiPh) devices are silicon-based integrated-circuit (IC) devices that may be used for a variety of optical-related functions such as, for example, guiding, generating, manipulating, and detecting light. This light may include any selected segment or segments of the electromagnetic radiation spectrum within and near the visible light spectrum (e.g., from ultraviolet, through visible, to infrared light). SiPh devices include, for example, waveguides, resonators, couplers, splitters, and rotators. SiPh devices may be fabricated on a silicon-on-insulator (SOI) wafer using a complementary metal-oxide-semiconductor (CM OS) fabrication process.

### BRIEF DESCRIPTION OF THE DRAWINGS

Aspects of the present disclosure are best understood from the following detailed description when read with the accompanying figures. The figures are drawn to clearly illustrate relevant aspects of the embodiments. The figures may illustrate relationships between various structures and/or elements within the embodiments. It is noted that the figures are not necessarily drawn to scale. In some instances, the dimensions of the various features may be arbitrarily increased or reduced for clarity of discussion.

FIG. 1 illustrates a simplified cross section of a portion of an example support wafer and a portion of an example corresponding photonic wafer at a stage prior to their bonding and further processing.

FIG. 2 illustrates a simplified cross section of an example bonded wafer after the bonding of the support wafer and the photonic wafer of FIG. 1.

FIG. 3 illustrates a simplified cross section of a bonded wafer corresponding to the bonded wafer of FIG. 2 following thinning and oxide deposition.

FIG. 4 illustrates a simplified cross section of a wafer corresponding to the wafer of FIG. 3 following the photolithographic etching of a cavity in the SiPh portion.

FIG. 5 illustrates a simplified cross section of a wafer corresponding to the wafer of FIG. 4 following the photolithographic etching of SiPh features in the bulk silicon of the cavity.

FIG. 6 illustrates a simplified cross section of a wafer corresponding to the wafer of FIG. 5 following the photolithographic etching of a cavity in the bulk silicon of the pad portion.

FIG. 7 illustrates a simplified cross section of a wafer corresponding to the wafer of FIG. 6 following the deposition of an oxide layer over the photonic wafer.

FIG. 8 illustrates a simplified cross section of a wafer corresponding to the wafer of FIG. 7 following the etching of pad access holes in the pad portion.

FIG. 9 illustrates a simplified cross section of a wafer corresponding to the wafer of FIG. 8 following the deposition and shaping of an input/output (I/O) pad in the pad portion of the photonic wafer.

FIG. 10A illustrates a simplified cross section of a bonded wafer in accordance with some alternative embodiments of the disclosure.

FIG. 10B illustrates a simplified cross section of a bonded wafer in accordance with some alternative embodiments of the disclosure.

FIG. 10C illustrates a simplified cross section of a bonded wafer in in accordance with some alternative embodiments of the disclosure.

FIG. 11 illustrates simplified perspective views of various passive SiPh feature examples that may be implemented in the SiPh portions described above.

FIG. 12 is a flowchart illustrating an example method of forming an IC device in accordance with some embodiments of the disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. In some embodiments, the terms “approximately” and/or “about” can be interpreted as meaning +/−10% or +/−5%, while in other embodiments, the terms “approximately” and/or “about” can be interpreted as meaning within the normal fabrication tolerances of a given fab manufacturing flow.

As noted above, silicon photonics (SiPh) devices may be fabricated on a silicon-on-insulator (SOI) wafer. An SOI wafer typically comprises a silicon device layer, a buried silicon dioxide (SiO₂, also referred to as silicon oxide) layer, and a base substrate layer. The buried silicon dioxide layer may be referred to as a buried oxide (BOX) layer or an oxide layer. The device layer is where the SiPh devices are fabricated. Other elements, such as, for example, transistors, may also be formed in this device layer. The silicon dioxide layer is the insulator layer, while the substrate layer provides mechanical support. Fabricating an SOI wafer typically requires two source wafers, which makes their fabrication relatively expensive. These source wafers may be referred to as a handle wafer and a donor wafer. One process for fabricating an SOI wafer from a handle wafer and a donor wafer is the bonded SOI (BSOI) process in which (a) the handle wafer undergoes oxidation to transform the top portion of the handle layer into the oxide layer, (b) the donor wafer is then bonded to the handle wafer via that oxide layer to form a bonded wafer, and (c) the donor wafer portion of the bonded wafer is then thinned, e.g., using chemical-mechanical polishing (CMP), to leave an SOI wafer with a silicon device layer (from the donor wafer) over the insulating oxide layer that is over the substrate (from the handle wafer).

While this process generates an SOI wafer having a desired form and function, it is relatively expensive since it uses two source wafers to generate a single SOI wafer and where much of the donor wafer is discarded in the thinning process. Fabrication methods that allow formation of an insulating layer and a device layer over a substrate while avoiding discarding much of a donor wafer would reduce overall costs for fabricating SiPh devices and increase their economic efficiency. Combining the fabrication of SiPh devices with the fabrication of CMOS image sensors (CIS) may provide such an economically more efficient fabrication method that reduces waste.

CM OS image sensors (CIS) are photon-processing integrated circuits that use arrays of pixel elements to convert incident light into electric signals to generate corresponding digital images or other information corresponding to the incident light. A typical pixel element includes a photodiode, a capacitor, and a set of transistors. CIS, as the name suggests, are manufactured using CMOS technology. A CIS may be fabricated in a composite process that includes fabricating a backside-illuminated (BSI) wafer, fabricating a corresponding support-circuitry IC wafer, bonding them together, and then singulating the wafer into individual devices. The CIS portion includes pixel elements while the support-circuitry IC portion provides logic, memory, control, and/or other functionality to the pixel elements. The support-circuitry IC wafer may be referred to as an application-specific IC (ASIC) wafer. Notably, the fabrication of the BSI CIS portion includes the deposition of one or more silicon oxide layers over a silicon substrate. Once flipped and bonded to the A SIC wafer, the resultant bonded wafer may offer regions of silicon on silicon oxide regions—in other words, SOI regions—that may be used as a foundation for fabricating SiPh devices.

Accordingly, in some embodiments, a fabrication process includes separately fabricating an A SIC wafer and a corresponding CIS wafer. The CIS wafer has a pixel region and a separate undeveloped region. The undeveloped region comprises mostly a layer of silicon and a layer of oxide. The oxide layer may include some metal features (e.g., routing lines and/or dummy bond pads). The CIS wafer is bonded to the A SIC wafer using, for example, pixel-level hybrid bonding (PLHB), to generate a bonded wafer where the undeveloped regions may function as an SOI wafer, having a silicon layer on an insulator over a supporting handle layer in the form of the A SIC wafer. The undeveloped region is then processed to form SiPh features, while the pixel region is mask protected. In some implementations, the bonded wafer is a multi-part or multi-project wafer where the wafer is singulated into two or more groups of devices, where a first group comprises CIS devices comprising pixel arrays and supporting circuitry and a different second group comprises SiPh devices comprising SiPh features and supporting circuitry. A third group may comprise hybrid devices comprising both pixel arrays and SiPh features, as well as supporting circuitry. In another implementation, the bonded wafer is singulated into a group of substantially identical hybrid devices comprising both pixel arrays and SiPh features.

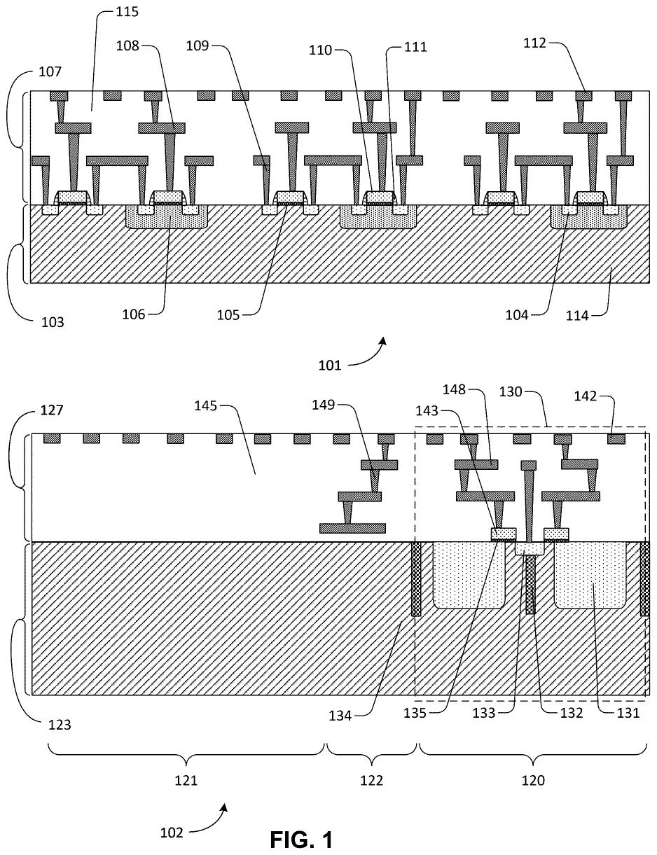

FIGS. 1-9 illustrate simplified cross-sectional view of various example stages of a fabrication of a bonded wafer comprising a CIS/SiPh wafer, referred to as a photonic wafer, and an A SIC wafer, referred to as a support wafer, in accordance with some embodiments of the disclosure. Although FIGS. 1-9 are described as a series of acts, it will be appreciated that these acts are not limiting in that the order of the acts can be altered in other embodiments, and the methods disclosed are also applicable to other structures. In some embodiments, some acts that are illustrated and/or described may be omitted in whole or in part. In some embodiment, additional acts that are not described herein may also be performed as part of the manufacturing process.

FIG. 1 illustrates a simplified cross section of a portion of an example support wafer 101 and a portion of an example corresponding photonic wafer 102 at a stage prior to their bonding and further processing. The support wafer 101 comprises a silicon layer 103 and an oxide layer 107. The silicon layer 103 may comprise bulk silicon 114 that has been variously processed in the fabrication of the support wafer 101. The processing may include, for example, doping, etching, deposition, filling, and/or any other suitable front-end-of-line (FEOL) process. Doped regions may include example doped wells 106, example doped current-carrying terminals 104, and other active regions, wells, and other doped structures (not shown). The doped regions may be (a) n-type doped using, for example, phosphorous (P), antimony (Sb), arsenic (As), or any suitable n-type dopant or (b) p-type doped using, for example, boron (B), aluminum (AI), indium (In), gallium (Ga), or any suitable p-type dopant. The current-carrying terminals 104 may be source or drain terminals, depending on configuration. Etched and filled regions may include, for example, shallow trench isolation (STI) structures and deep trench isolation (DTI) structures (not shown).

The doping of selected regions of bulk silicon may use, for example, ion implantation or thermal diffusion of the selected dopant. Photolithographic etching may comprise depositing a photoresist via, e.g., a spin coating process, then selectively exposing the photoresist to electromagnetic radiation based on a photo mask, hereupon the electromagnetic radiation modifies a solubility of exposed regions of the photoresist to define soluble regions. The soluble parts are then removed to leave behind a pattern for etching. An etchant—e.g. a dry etchant such as, for example, a gaseous or plasma mixture of fluorine (F) and other elements (e.g. xenon (e.g., X eF₂, X eF₆), sulfur (e.g., SF₆), and carbon (e.g., CF₄))—is then used to remove material in the areas exposed by the etching pattern. Deposition of materials may be by, for example, atomic layer deposition (ALD), chemical vapor deposition (CVD), physical vapor deposition (PVD), remote plasma CVD (RPCVD), plasma enhanced CVD (PECVD), metal organic CVD (MOCVD), sputtering, plating, spin-on techniques, other suitable processes, and/or combinations thereof. Filling a feature may be performed by, for example, first etching a corresponding trench, then depositing the fill material over the wafer to fill the trench, and then polishing the wafer to remove the fill material from areas outside of the filled trench.

The oxide layer 107, which may also be referred to as a dielectric layer, may comprise silicone dioxide 115 that functions as an interlayer dielectric (ILD), conductive routing lines 108, conductive vias 109, conductive bond pads 112, gate terminals 110, gate insulators 105, and spacers 111. The conductive routing lines 108, conductive vias 109, and bond pads 112, which may be generally referred to as conductive interconnects, may comprise copper (Cu), aluminum (Al), or any other suitable conductive material. The conductive routine lines 108 which may be distributed over multiple layers-are used to interconnect among components of the support wafer 101 as well as to connect-via, e.g., the bond pads 112-to external components. The layer of the bond pads 112-which is located at the top boundary of the oxide layer 107, opposite the bottom boundary adjacent to the silicon layer 103-may also be considered a metallization layer. The conductive vias 109 are used to connect between metallization layers.

The gate terminals 110 comprise a conductive material such as titanium (Ti), titanium nitride (TIN), tungsten (W), tantalum nitride (TaN), copper, aluminum, doped polysilicon, or any other suitable conductive material. The gate insulator 105 may comprise high-k dielectric material, such as, for example, hafnium oxide (HfO₂), zirconium oxide (ZrO₂), aluminum oxide (Al₂O₃), magnesium oxide (MgO), hafnium silicon oxide (HfSiO), hafnium silicon oxynitride (HfSiON), hafnium tantalum oxide (HfTaO), hafnium titanium oxide (HfTiO), hafnium titanium tantalum oxide (HfTiTaO), hafnium aluminum oxynitride (HfAION), hafnium zirconium oxide (HfZrO), other suitable high-k dielectric materials, or combinations thereof. The oxide layer 107 may be formed using a series and combination of deposition, masking, etching, polishing, and/or any other suitable back-end-of-line (BEOL) processes. Notably, the silicon dioxide 115 may include an aggregation of multiple depositions of SiO₂ performed in conjunction with the formation of various levels of conductive interconnects.

It should be noted that either, or both, of the silicon layer 103 and the oxide layer 107 may comprise additional components such as, for example, capacitors, resistors, inductors, and other devices (not shown). It should also be noted that the oxide layer 107 may also comprise transistors such as, for example, thin-film transistors (TFTs) or other 3D transistors. It should be further noted that while example support wafer 101 is shown as comprising planar FETs, the support wafer 101 may instead, or in addition, comprise 3D transistors such as, for example, fin field-effect transistors (finFETs) and/or gate-all-around FETs (GAAFETs).

The photonic wafer 102 comprises a silicon layer 123 and an oxide layer 127, which are horizontal subdivisions. The silicon layer 123 comprises bulk silicon 134 that has been variously processed in the fabrication of the below-described pixel cells 130. The processing may include any of the processing methods described above. The oxide layer 127 comprises silicon dioxide 145, which functions as an ILD and, as described elsewhere herein, will also function as an insulator layer under the silicon 134 for an SOI-like structure for the silicon-photonics features that will be fabricated in accordance with some embodiments of the disclosure, as described further below. The oxide layer 127 also comprises conductive routing lines 148, conductive vias 149, conductive bond pads 142, transfer gates 143, and gate insulators 135. These elements of the oxide layer 127 may be substantially similar to the corresponding elements of the oxide layer 107 of the support wafer 101 described above and, accordingly, may comprise similar materials and be fabricated using similar processes. The conductive bond pads 142 are located at the top boundary of the oxide layer 127, opposite the bottom boundary adjacent to the silicon layer 123.

The photonic wafer 102 may also be vertically subdivided into an image-sensor portion 120, a silicon-photonics (SiPh) portion 121, and a pad portion 122. The image-sensor portion 120 comprises an array of pixel cells 130. In some embodiments, each pixel cell 130 may include, for example, four photodetectors 131 arranged in the bulk silicon 134 around a floating diffusion (FD) node 133. Each photodetector 131 is selectively connectible to its corresponding FD node 133 subject to the control of a corresponding transfer gate 143. Each transfer gate 143 is insulated from components in the silicon layer 123 (such as, for example, the bulk silicon 134) by a corresponding gate insulator 135. Photodetectors 131 may be walled-off from neighboring photodetectors 131 and/or other components by isolation structures 132, which reduce optical and electronic interference—e.g., latch-up, cross-talk, leakage currents, and the like between adjacent photodetectors 131.

Elements of the silicon layer 123 of the photonic wafer 102 corresponding to similar elements described above in reference to the silicon layer 103 of the support wafer 101 may comprise similar materials and be similarly formed. The isolation structures 132 may comprise suitable dielectric material and may be formed by etching and filling. The FD node 133 may be formed, for example, by etching and filling. The photodetector 131 may be formed, for example, by doping the corresponding region of bulk semiconductor 134.

The photodetector 131 is configured to generate charge carriers (e.g., electrons) in response to the absorption of incident photons (not shown). During an image-capture interval, the corresponding transfer gate 143 is enabled and charges accumulated by the photodetector 131 are transferred to the FD node 133. The FD node 133 may comprise a suitably doped region of the silicon layer 123. The charge on the FD node 133 may be used to control (via, e.g., a source-follower transistor) a voltage or current whose level corresponds to the accumulated charge and, accordingly, to the intensity of the photons incident on the photodetector 131 during the corresponding image-capture interval. A reset transistor (not shown) may be used to reset the FD node 133. Note that circuitry supporting the photodetectors 131—such as, e.g., a source-follower transistor or a reset transistor—may be implemented in either the photonic wafer 102 or the support wafer 101. In general, offloading support circuitry from the photonic wafer to the support wafer tends to allow increasing the number of pixel elements in the photonic wafer.

The SiPh portion 121 comprises, at this stage, bulk silicon 134, silicon dioxide 145, and bond pads 142. Notably, at least some (e.g., a subset) of the bond pads 142 in the SiPh portion 121 are dummy bond pads that are not connected to any circuit elements in the photonic wafer 102. Note that the image-sensor portion 120 and/or the pad portion 122 may also include bond pads 142 that are dummy pads that are not connected to circuit elements in the photonic waver 102. The relative and/or absolute number of dummy pads may be greater in the SiPh portion 121 than in either of the image-sensor portion 120 or pad portion 122. The dummy bond pads are, notably, used in the wafer bonding, as described below. After the wafer bonding, the SiPh devices will be formed in the SiPh portion 121.

The pad portion 122 comprises, at this stage, bulk silicon 134, silicon dioxide 145, conductive routing lines 148, conductive vias 149, and conductive bond pads 142. A conductive routing line 148 by the bottom boundary of the oxide layer 127, adjacent to the silicon layer 123, will later be connected to an I/O pad, as described below, to interconnect to components of the support wafer 101.

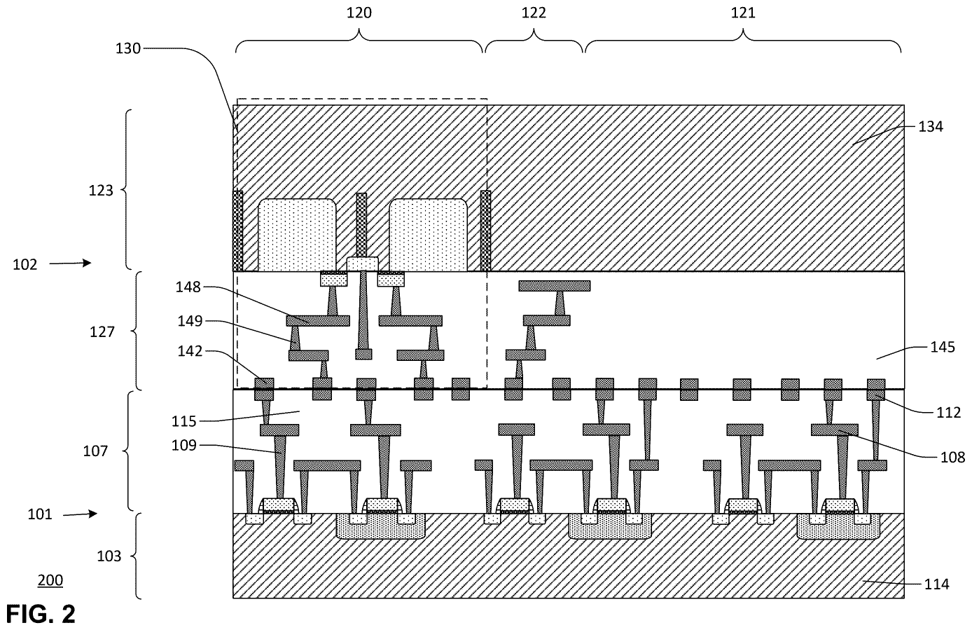

FIG. 2 illustrates a simplified cross section of an example bonded wafer 200 after the bonding of the support wafer 101 and the photonic wafer 102 of FIG. 1. The photonic wafer 102 is flipped over so that its bond pads 142 can be bonded to the corresponding bond pads 112 of the support wafer 101. The bonding process may be a pixel-level hybrid bonding (PLHB) process in which the respective bonding pads of the support wafer 101 and the photonic wafer 102 are precisely aligned and brought together. The two wafers are then annealed in order to bond the copper of the bond pads 112 to the copper of the bond pads 142 and, in some embodiments, a portion of the oxide region 145 and bond the silicon dioxide 115 of the oxide layer 107 to the silicon dioxide 145 at the boundary of the oxide region 127 and, in some embodiments, a portion of the bond pad 142. This bonding allows the pixel cells 130 of the photonic wafer 102 to use the corresponding support circuitry of the support wafer 101.

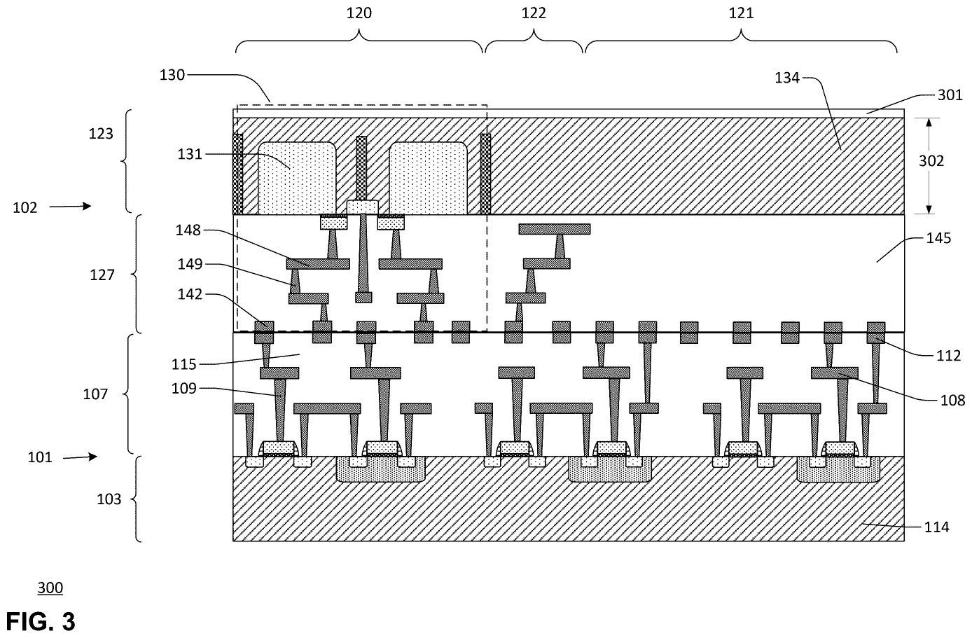

FIG. 3 illustrates a simplified cross section of a bonded wafer 300 corresponding to the bonded wafer 200 of FIG. 2 following thinning and oxide deposition. The silicon layer 134 of the bonded wafer 200 is thinned using, for example, a chemical mechanical planarization (CMP) process. The thinning of the silicon layer 134 increases its transparency so that incident photons are more likely to penetrate through to the photodetectors 131 of the pixel cells 130. Note that, accordingly, the image-sensor portion 120 may be considered to comprise back-side-illuminated (BSI) image sensors. The thinning also reduces the thickness of the silicon layer 134 to a thickness 302 closer to that of the silicon layer of SOI wafers, which makes the subsequent processing steps easier. Following the thinning, a layer 301 of silicon dioxide is deposited over the silicon layer 134 as a coating.

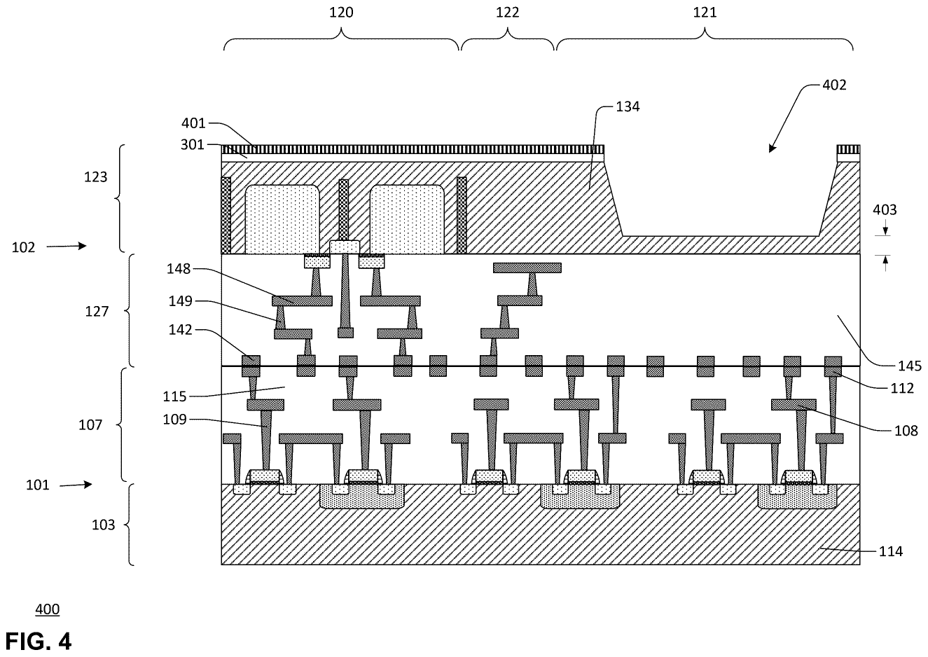

FIG. 4 illustrates a simplified cross section of a wafer 400 corresponding to the wafer 300 of FIG. 3 following the photolithographic etching of a cavity 402 in the SiPh portion 121. A patterned photoresist 401 is developed over the oxide layer 301 using a photolithographic process as described above and is then used to etch out cavity 402 in the bulk silicon 134. The etching reduces the thickness of the bulk silicon 134 in the cavity 402 to a thickness 403 that is in the range for a typical SOI wafer used for SiPh devices.

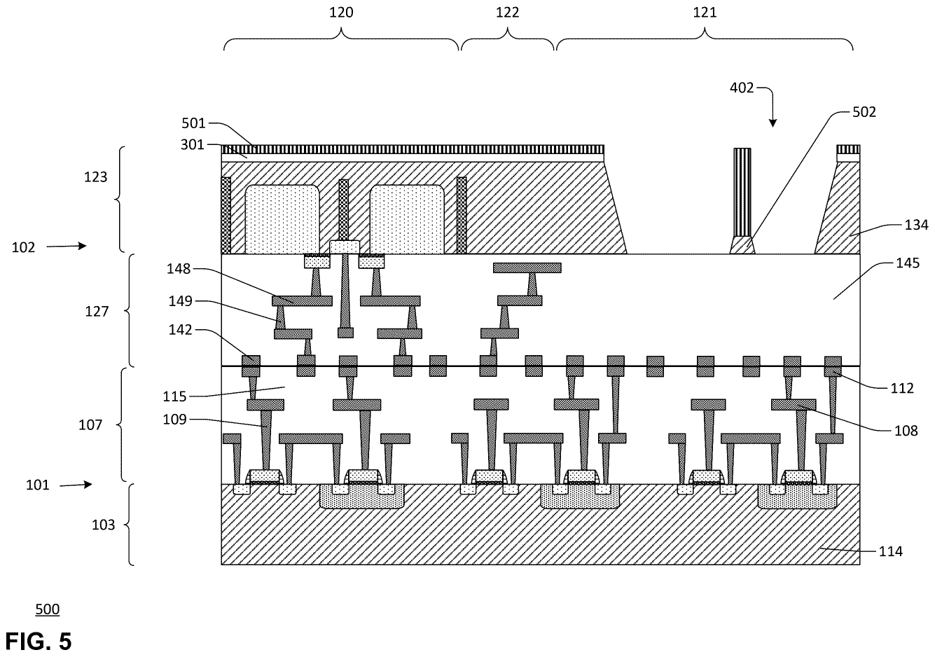

FIG. 5 illustrates a simplified cross section of a wafer 500 corresponding to the wafer 400 of FIG. 4 following the photolithographic etching of a SiPh feature 502 in the bulk silicon 134 of the cavity 402. After removing the patterned photoresist 401, a new patterned photoresist 501 is developed over the silicon layer 123 that is used to etch out one or more SiPh features 502, such as, for example, an optical waveguide. SiPh features are described in greater detail further below.

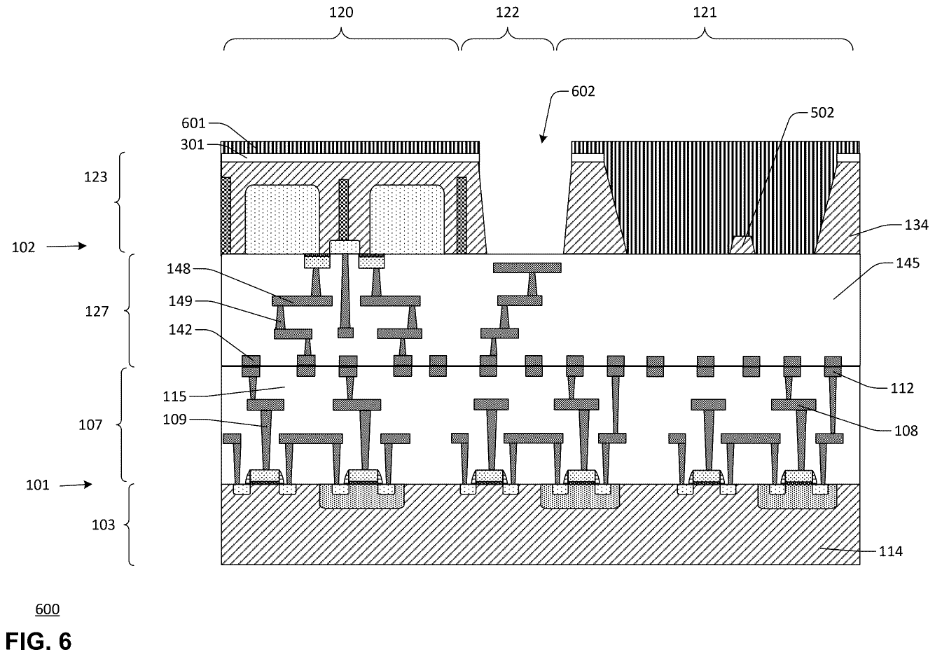

FIG. 6 illustrates a simplified cross section of a wafer 600 corresponding to the wafer 500 of FIG. 5 following the photolithographic etching of a cavity 602 in the bulk silicon of the pad portion 122. After the removing the patterned photoresist 501, a new patterned photoresist 601 is developed over the photonic wafer 102 and is used to etch out the pad access cavity 602 that exposes a region of the oxide layer 127 in the pad portion 122.

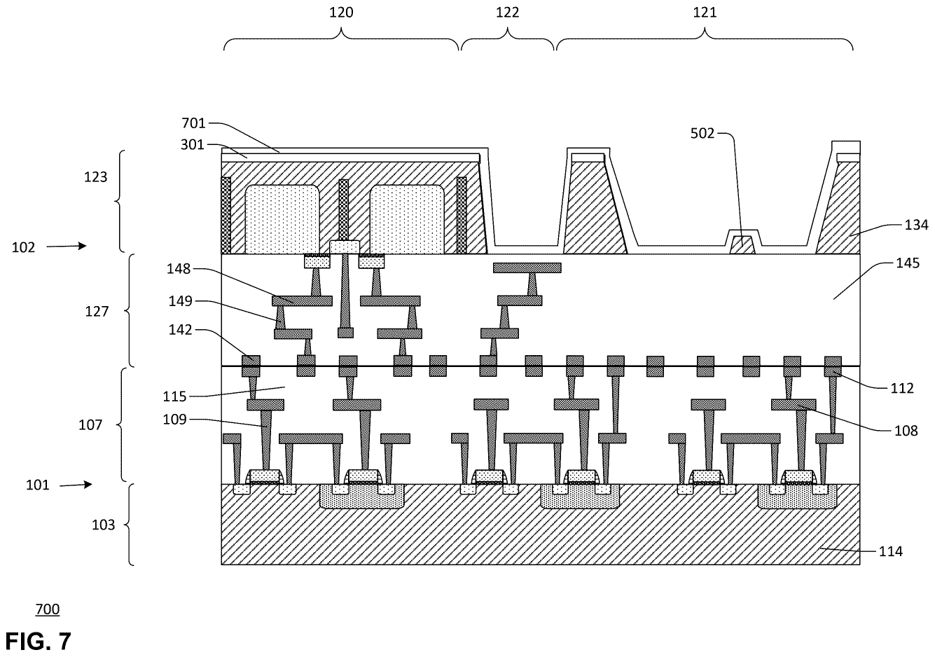

FIG. 7 illustrates a simplified cross section of a wafer 700 corresponding to the wafer 600 of FIG. 6 following the deposition of an oxide layer 701 over the photonic wafer 102. After removing the patterned photoresist 601, a layer 701 of silicon dioxide is deposited over the photonic wafer 102. The oxide layer provides passivation protection for components of the photonic wafer 102 and, importantly, provides desired optical characteristics to the SiPh feature 502. Notably, the refractive index, n, of Si is approximately 3.5, while the refractive index of silicon dioxide is approximately 1.44. This difference in refractive index helps suitable electromagnetic waves reflect internally within the Si features almost losslessly.

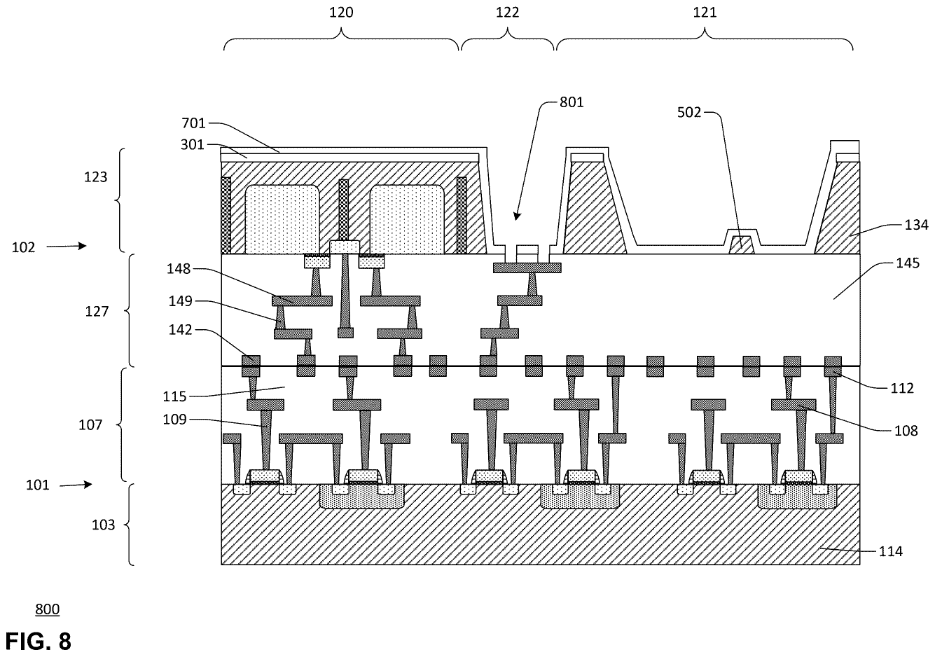

FIG. 8 illustrates a simplified cross section of a wafer 800 corresponding to the wafer 700 of FIG. 7 following the etching of pad access holes 801 in the pad portion 122. The access holes 801 may be formed via the etching processes described above. The access holes 801 go through the oxide layer 701 and a portion of the oxide layer 127 to access a conductive platform of the conductive routing lines 148, which is part of the conductive interconnects of the wafer 800.

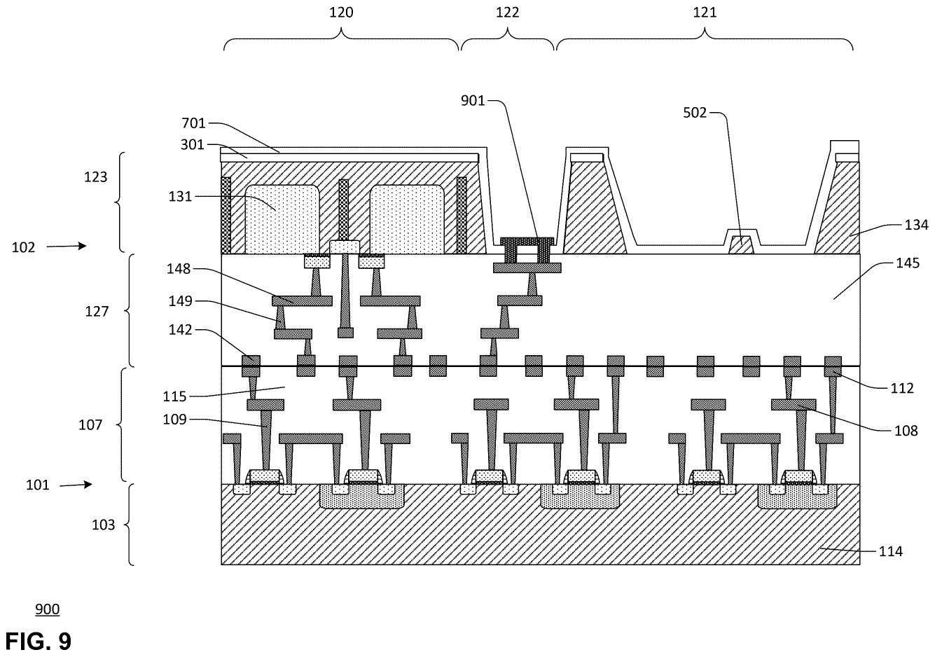

FIG. 9 illustrates a simplified cross section of a wafer 900 corresponding to the wafer 800 of FIG. 8 following the deposition and shaping of an input/output (I/O) pad 901 in the pad portion 122 of the photonic wafer 102. The I/O pad 901 may be formed by depositing, e.g., by sputtering, a metal such as, for example, aluminum, atop the photonic wafer 102. This fills in the cavities 801 and forms a metallic layer over the oxide layer 701. Then, photolithographic etching may be used to remove most of the deposited metal leaving behind select segments such as I/O pad 901. The I/O pad 901 may provide a conductive path to devices in the support wafer 101 via the conductive interconnects of the photonic wafer 102 and the support wafer 101.

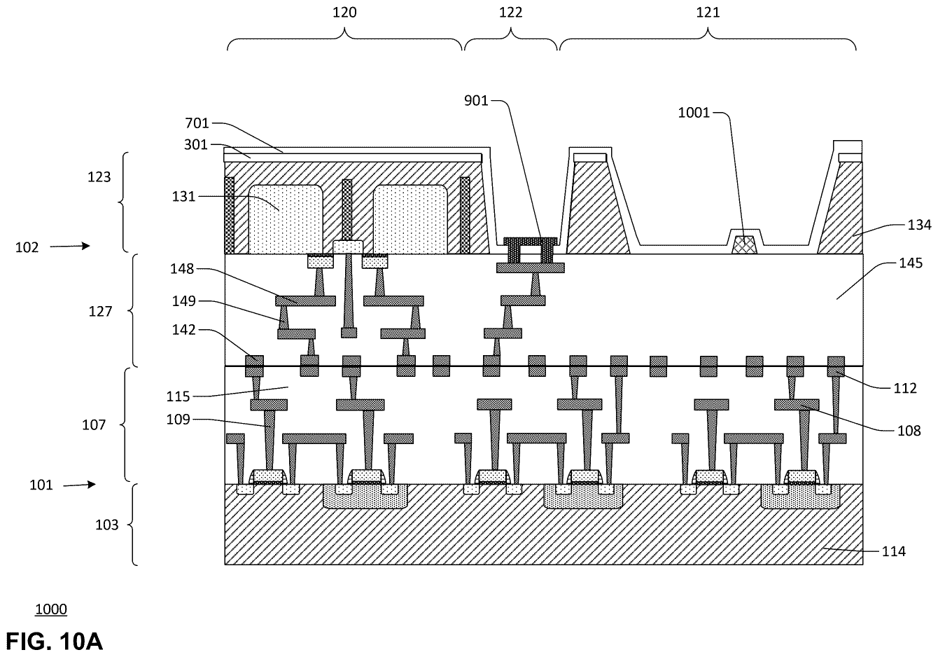

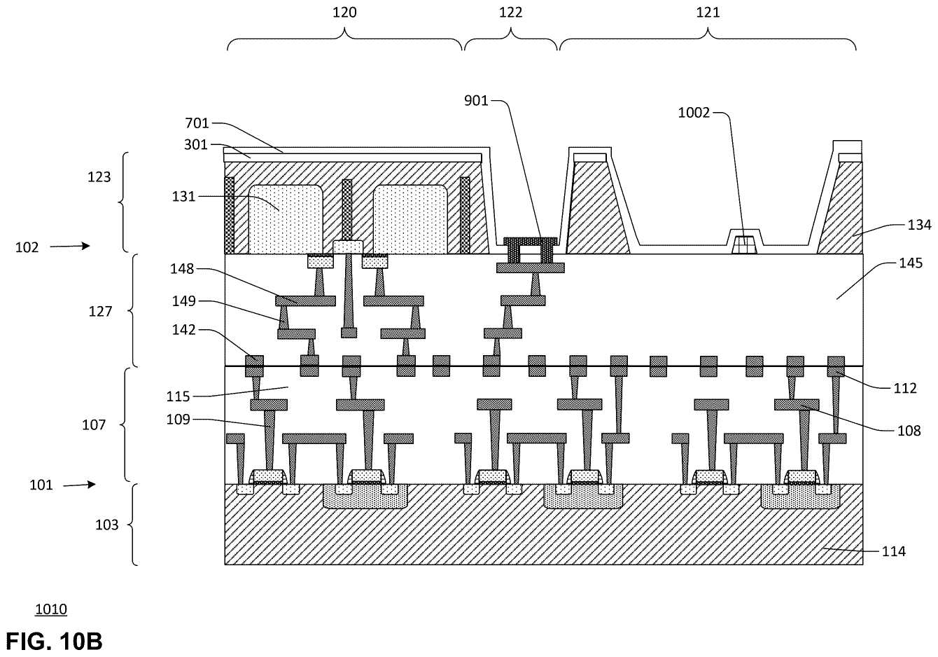

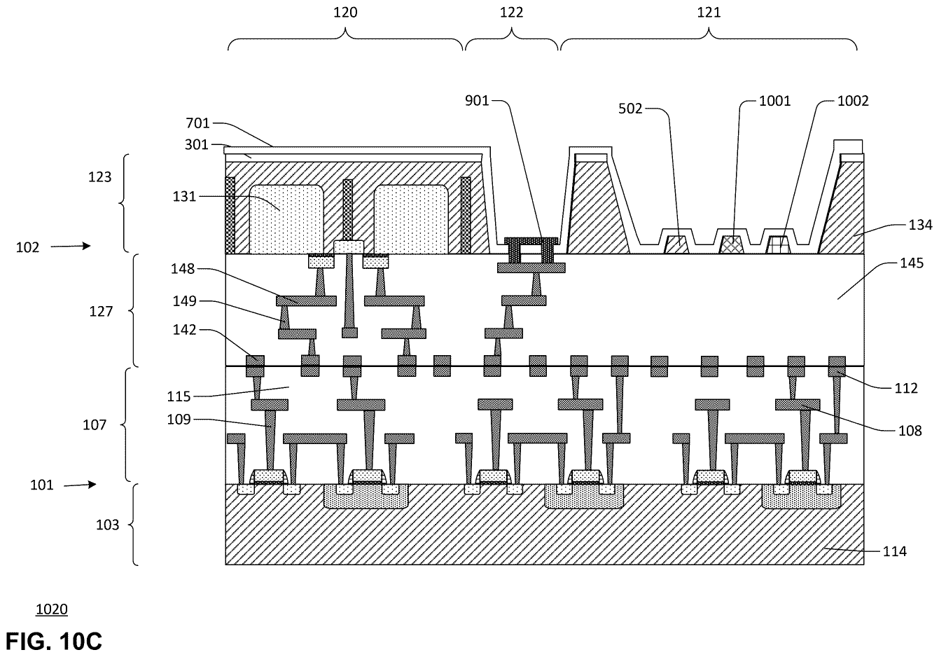

FIG. 10A illustrates a simplified cross section of a bonded wafer 1000 in accordance with some alternative embodiments of the disclosure. The SiPh portion 121 of the wafer 1000 comprises a SiPh feature 1001 that comprises silicon nitride (abbreviated as SiN) instead of the silicon SiPh feature 502 of FIG. 9. The SiN SiPh feature 1001 provides for photonics features suited for wavelengths different from the wavelengths for which silicon SiPh features are suited for, as described further below. The feature 1001 may be formed by, for example, etching the bulk silicon in the SiPh portion 121 deeper than described in reference to the wafer 400 of FIG. 4, reaching all the way down to the oxide layer 127. Then, depositing and etching SiN to form the feature 1001. Note that in some alternative embodiments, SiN feature 1001 may be formed by forming a corresponding Si feature, as shown, for example, in FIG. 5, and then nitriding that silicon features to introduce nitrogen into the silicon features and transform it into a SiN feature.

FIG. 10B illustrates a simplified cross section of a bonded wafer 1010 in accordance with some alternative embodiments of the disclosure. The SiPh portion 121 of the wafer 1010 comprises a SiPh feature 1002 that comprises silicon oxynitride (abbreviated as SiON) instead of the silicon SiPh feature 502 of FIG. 9. The SiON SiPh feature 1002 provides for photonics features suited for wavelengths different from the wavelengths for which silicon SiPh features are suited for, as described further below. The feature 1002 may be formed by, for example, etching the bulk silicon in the SiPh portion 121 deeper than described in reference to the wafer 400 of FIG. 4, reaching all the way down to the oxide layer 127. Then, depositing and etching SiON to form the feature 1002. Note that in some alternative embodiments, SiON feature 1002 may be formed by forming a corresponding Si feature, as shown, for example, in FIG. 5, and then nitriding that silicon features to introduce nitric oxide into the silicon features and transform it into a SiON feature.

FIG. 10C illustrates a simplified cross section of a bonded wafer 1020 in accordance with some alternative embodiments of the disclosure. The SiPh portion 121 of the wafer 1020 comprises SiPh features 1001 that comprise silicon nitride (abbreviated as SiN) and SiPh features 1002 that comprise silicon oxynitride (abbreviated as SiON) in addition to silicon SiPh features 502. The features 1001 and 1002 may be formed, for example, following the formation of the SiPh feature 502 as shown in FIG. 5, depositing and etching SiN and SiON, respectively, to form the features 1001 and features 1002. Note that in some alternative embodiments, SiN and/or SiON features be formed by forming corresponding Si features, as shown, for example, in FIG. 5, and then nitriding those silicon features to introduce nitrogen or nitric oxide into the silicon features and transform them into SiN or SiON features, respectively.

It should be noted that some alternative embodiments (now shown) may have Si, SiN, and SiON photonics features in the SiPh portion. Other alternative embodiments may have any other combination of these materials such as, for example, SiN only, SiOn only, Si and SiN, and Si and SiON. Each of these materials is best suited for transmitting a different corresponding range of electromagnetic wavelengths. Si is suited for short wavelength infra red (SWIR) light, whose wavelength ranges between approximately 1400 and 3000 nanometers (nm). SiON is suited for near infra red (NIR) light, whose wavelength ranges between approximately 780 and 2500 nm. SiN is suited for visible light, whose wavelength ranges between approximately 380 and 700 nm. Accordingly, using different combinations of these materials allows for wide flexibility in customizing devices for particular use cases.

It should also be noted that example wafer 900 of FIG. 9 and example wafers 1000/1010/1020 of FIGS. 10A/10B/10C may each be further processed to add filters (e.g., color filters) and/or micro-lenses (not shown) over corresponding photodetectors 131 in the image-sensor portions 120 of the wafers. The color filters may be used to determine the colors in an image, while the micro-lenses may be used to enhance the photon reception of the photodetectors 131.

Following the above-described fabrication steps, the bonded wafers (e.g., wafers 900 or wafer 1000/1010/1020) are singulated into individual dies. In the singulated devices, the segment corresponding to the support wafer may be referred to as the support die and the segment corresponding to the photonic wafer may be referred to as the photonic die. In some implementation, the wafer is a multi-project wafer where the singulation generates a set of image-sensor dies from the image-sensor portion 120 and a set of SiPh dies from the SiPh portion 121. The image-sensor dies and SiPh dies may each have corresponding I/O pads from the pad portion 122. The resulting image-sensor dies and SiPh dies may be substantially conventional dies where, for example, the SiPh dies transmit and/or receive light signals to and/or from optical fibers using suitable fiber-optic interfaces. Note that the support circuitry in the respective dies will also be different. In fact, in some implementations, the support circuitry in the SiPh dies may be minimal or even absent. In some other implementations, the singulation generates a set of heterogenous device dies, where each die includes image-sensor devices and silicon-photonics devices, which may be functionally integrated in any suitable manner.

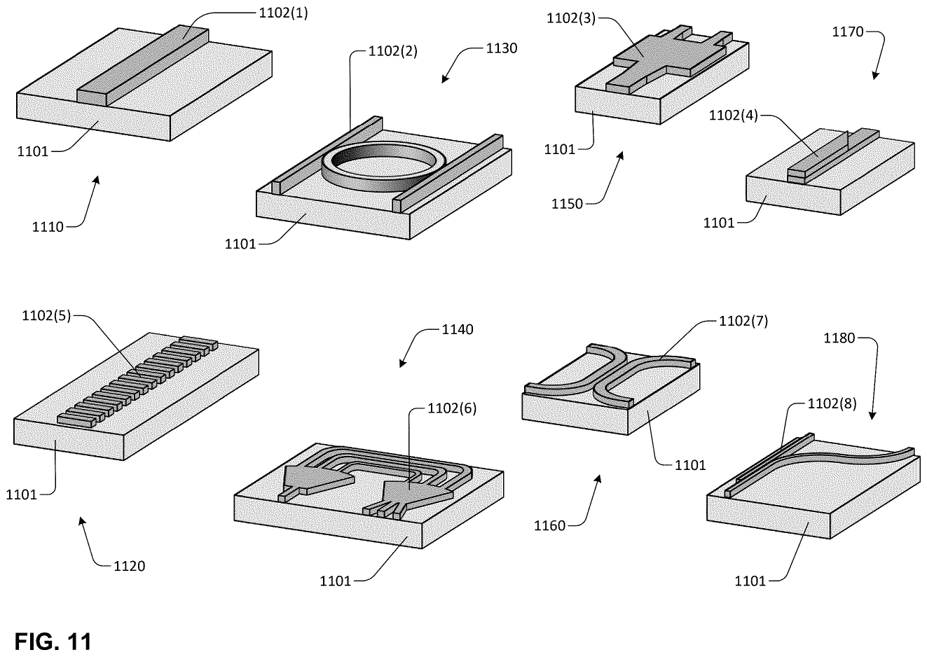

FIG. 11 illustrates simplified perspective views of various passive SiPh feature examples that may be implemented in the SiPh portions 121 described above. The various SiPh feature examples are shown as a SiPh feature 1102 over a silicon dioxide base 1101. The SiPh feature 1102 may comprise, for example, any of Si, SiN, or SiON. Example 1110 is a strip waveguide. Example 1120 is a subwavelength grating (SWG) waveguide. Examples 1110 and 1120 may be used for signal routing. Example 1130 is a ring resonator. Example 1140 is an arrayed waveguide grating. Examples 1130 and 1140 may be used for signal filtering. Example 1150 is a multimode coupler. Example 1160 is a directional coupler. Examples 1150 and 1160 may be used for signal splitting. Example 1170 is a polarization rotator. Example 1180 is a polarization splitter. Examples 1170 and 1180 may be used for signal polarization.

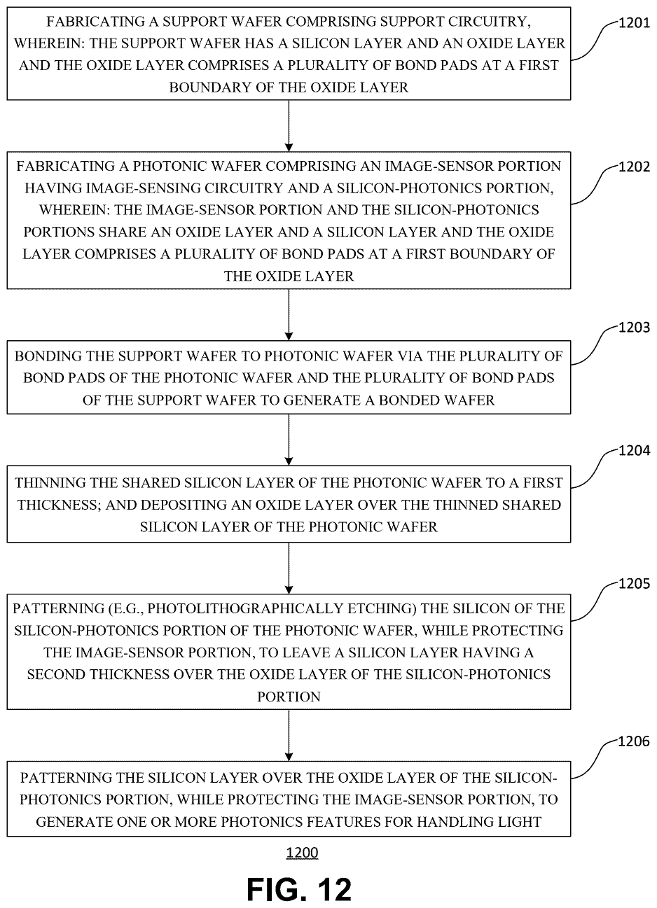

FIG. 12 is a flowchart illustrating an example method 1200 of forming an IC device in accordance with some embodiments of the disclosure. Although this method and other methods illustrated and/or described herein are illustrated as a series of acts or events, it will be appreciated that the present disclosure is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included. A cts can correspond, for example, to the structures previously illustrated in FIGS. 2-12 in some embodiments.

Act 1201 includes fabricating a support wafer comprising support circuitry, wherein the support wafer has a silicon layer and an oxide layer and the oxide layer comprises a plurality of bond pads at a first boundary of the oxide layer. FIG. 1 illustrates a view of an embodiment corresponding to act 1201.

Act 1202 includes fabricating a photonic wafer comprising an image-sensor portion having image-sensing circuitry and a silicon-photonics portion, wherein the image-sensor portion and the silicon-photonics portions share an oxide layer and a silicon layer and the oxide layer comprises a plurality of bond pads at a first boundary of the oxide layer. FIG. 1 illustrates a view of an embodiment corresponding to act 1202.

Act 1203 includes bonding the support wafer to photonic wafer via the plurality of bond pads of the photonic wafer and the plurality of bond pads of the support wafer to generate a bonded wafer. FIG. 2 illustrates a view of an embodiment corresponding to act 1203.

Act 1204 includes thinning the shared silicon layer of the photonic wafer to a first thickness and depositing an oxide layer over the thinned shared silicon layer of the photonic wafer. FIG. 3 illustrates a view of an embodiment corresponding to act 1204.

Act 1205 includes patterning, e.g. photolithographically etching, the silicon of the silicon-photonics portion of the photonic wafer, while protecting the image-sensor portion, to leave a silicon layer having a second thickness over the oxide layer of the silicon-photonics portion. FIG. 4 illustrates a view of an embodiment corresponding to act 1205.

Act 1206 includes patterning, e.g. photolithographically etching, the silicon layer over the oxide layer of the silicon-photonics portion, while protecting the image-sensor portion, to generate one or more photonics features for handling light. FIG. 5 illustrates a view of an embodiment corresponding to act 1206.

Accordingly, in some embodiments, the present disclosure relates to an integrated circuit (IC) device including (a) a support die having support circuitry and (b) a photonic die having an image-sensor portion including image-sensing circuitry and a silicon-photonics portion having photonics features. The image-sensor portion and the silicon-photonics portion of the photonic die share an oxide layer including a plurality of bond pads at a first boundary of the oxide layer. The support die includes an oxide layer having a plurality of bond pads at a first boundary of the oxide layer. The support die is bonded to the photonic die via the plurality of bond pads of the photonic die and the plurality of bond pads of the support die. The support circuitry is configured to provide support functionality to the image-sensor portion.

In other embodiments, the present disclosure relates to a method including (a) fabricating a support die having support circuitry, (b) fabricating a photonic die including an image-sensor portion including image-sensing circuitry and a silicon-photonics portion including photonics features, and (c) bonding the support die to the photonic die via the plurality of bond pads of the photonic die and the plurality of bond pads of the support die. The image-sensor portion and the silicon-photonics portion of the photonic die share an oxide layer having a plurality of bond pads at a first boundary of the oxide layer. The support die includes an oxide layer having a plurality of bond pads at a first boundary of the oxide layer. The support circuitry is configured to provide support functionality to the image-sensor portion.

In yet other embodiments, the present disclosure relates to a method including (a) fabricating a support wafer having support circuitry, wherein the support wafer has a silicon layer and an oxide layer and the oxide layer includes a plurality of bond pads at a first boundary of the oxide layer, (b) fabricating a photonic wafer including an image-sensor portion having image-sensing circuitry and a silicon-photonics portion, wherein the image-sensor portion and the silicon-photonics portions share an oxide layer and a silicon layer and the oxide layer includes a plurality of bond pads at a first boundary of the oxide layer, and (c) bonding the support wafer to photonic wafer via the plurality of bond pads of the photonic wafer and the plurality of bond pads of the support wafer to generate a bonded wafer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. An integrated circuit (IC) device comprising:
a support die comprising support circuitry; and
a photonic die comprising:
an image-sensor portion comprising image-sensing circuitry; and
a silicon-photonics portion comprising photonics features, wherein:
the image-sensor portion and the silicon-photonics portion of the photonic die share an oxide layer comprising a plurality of bond pads at a first boundary of the oxide layer;
the support die comprises an oxide layer comprising a plurality of bond pads at a first boundary of the oxide layer;
the support die is bonded to the photonic die via the plurality of bond pads of the photonic die and the plurality of bond pads of the support die; and
the support circuitry is configured to provide support functionality to the image-sensor portion.

2. The IC device of claim 1, wherein the support die is also bonded to the photonic die via an oxide of the oxide layer of the support die and an oxide of the shared oxide layer of the photonic die.

3. The IC device of claim 1, wherein:
a first subset of the plurality of bond pads of the photonic die is located in the silicon-photonics portion; and
the bond pads of the first subset are dummy bond pads.

4. The IC device of claim 1, wherein the photonic die further comprises a pad portion comprising an input/output (I/O) pad conductively connected to the support circuitry of the support die.

5. The IC device of claim 1, wherein the photonics features comprise at least one of silicon (Si) feature, silicon nitride (SiN) features, and silicon oxynitride (SiON) features.

6. The IC device of claim 1, wherein the photonics features comprise at least two of silicon (Si) features, silicon nitride (SiN) features, and silicon oxynitride (SiON) features.

7. The IC device of claim 1, wherein the photonics features comprise silicon (Si) features, silicon nitride (SiN) features, and silicon oxynitride (SiON) features.

8. The IC device of claim 1, wherein the photonics features comprise one or more of a waveguide, a resonator, a coupler, a polarization rotator, a grating, and a splitter.

9. A method comprising:
fabricating a support die comprising support circuitry, the fabricating including depositing an oxide layer for the support die and forming a plurality of bond pads at a first boundary of the oxide layer;
fabricating a photonic die, the fabricating including:
forming an image-sensor portion having image-sensing circuitry; and
forming a silicon-photonics portion, wherein the image-sensor portion and the silicon-photonics portion of the photonic die share a shared oxide layer; and
forming a plurality of bond pads at a first boundary of the shared oxide layer of the photonic die;
bonding the support die to the photonic die via the plurality of bond pads of the photonic die and the plurality of bond pads of the support die; and
forming photonics features in the silicon-photonics portion of the bonded photonic die.

10. The method of claim 9, wherein the bonding further comprises bonding the support die to the photonic die via an oxide of the oxide layer of the support die and an oxide of the shared oxide layer of the photonic die.

11. A method comprising:
fabricating a support wafer comprising support circuitry, the fabricating including depositing an oxide layer for the support wafer and forming a plurality of bond pads at a first boundary of the oxide layer;
fabricating a photonic wafer, the fabricating comprising:
forming an image-sensor portion having image-sensing circuitry; and
forming a silicon-photonics portion, wherein the image-sensor portion and the silicon-photonics portion share a shared oxide layer and share a silicon layer; and
forming a plurality of bond pads at a first boundary of the shared oxide layer of the photonic wafer; and
bonding the support wafer to the photonic wafer via the plurality of bond pads of the photonic wafer and the plurality of bond pads of the support wafer to generate a bonded wafer.

12. The method of claim 11, further comprising:
thinning the shared silicon layer of the photonic wafer to a first thickness; and
depositing an oxide layer over the thinned shared silicon layer of the photonic wafer.

13. The method of claim 12, further comprising patterning the silicon of the silicon-photonics portion of the photonic wafer, while protecting the image-sensor portion, to leave a silicon layer having a second thickness over the oxide layer of the silicon-photonics portion.

14. The method of claim 13, further comprising patterning the silicon layer over the oxide layer of the silicon-photonics portion, while protecting the image-sensor portion, to generate one or more photonics features for handling light.

15. The method of claim 14, further comprising depositing an oxide layer over the photonics features of the photonic wafer.

16. The method of claim 15, further comprising forming at least one of filters and micro-lenses over the image-sensor portion of the photonic wafer.

17. The method of claim 14, further comprising depositing and etching at least one of a layer of silicon nitride and a layer of silicon oxynitride, while protecting the image-sensor portion, to form at least one of a silicon nitride photonics feature and a silicon oxynitride photonics feature.

18. The method of claim 14, wherein:
the bonded wafer is a multi-project wafer; and
the method further comprises singulating the bonded wafer to generate:
a set of image-sensor dies from the image-sensor portion; and
a set of silicon-photonics dies from the silicon-photonics portion.

19. The method of claim 14, further comprising singulating the bonded wafer to generate a set of heterogenous image-sensor and silicon-photonics device dies.

20. The method of claim 12, further comprising:
photolithographically etching the silicon of the silicon-photonic portion of the photonic wafer, while protecting the image-sensor portion, to leave an exposed region of the oxide layer of the silicon-photonics portion;
depositing a layer of one of silicon nitride and silicon oxynitride; and
etching the deposited layer to form corresponding photonics features.
